(19) United States
(12) Patent Application Publication
(10) Pub. No.: US 2026/0114326 A1
(43) Pub. Date: Apr. 23, 2026

(54) POWER MODULE

(71) Applicant: Silergy Semiconductor Technology (Hangzhou) LTD, Hangzhou (CN)

(72) Inventors: Ke Dai, Hangzhou (CN); Jiajia Yan, Hangzhou (CN); Qiukai Huang, Hangzhou (CN); Chao Li, Hangzhou (CN); Jing Zhu, Hangzhou (CN)

(21) Appl. No.: 19/361,252

(22) Filed: Oct. 17, 2025

(30) Foreign Application Priority Data
Oct. 21, 2024 (CN) 202411472570.0

(51) Int. Cl. H01L 25/16; H01L 23/00; H01L 23/373; H01L 23/64

(52) U.S. Cl. CPC H10W 90/00; H10W 40/25; H10W 44/501; H10W 90/738

(57) ABSTRACT

A power module, can include: a substrate, including an interior having at least one bare die, and a top surface having a first pad; at least one inductor structure disposed on the top surface of the substrate, being configured to electrically connected to the bare die via the first pad, and having a magnetic core; and a thermal conductive structure, including a first portion formed between the top surface of the substrate and a bottom surface of the magnetic core, a second portion extending from the bottom surface of the magnetic core to a top surface of the magnetic core, and a third portion formed on the top surface of the magnetic core, where the first portion, the second portion, and the third portion are connected together.

### RELATED APPLICATIONS

This application claims the benefit of Chinese Patent Application No. 202411472570.0, filed on Oct. 21, 2024, which is incorporated herein by reference in its entirety.

### FIELD OF THE INVENTION

The present invention generally relates to the field of semiconductor technology, and more particularly to power modules.

### BACKGROUND

Power modules are commonly used to supply power to core components of equipment (e.g., the core of a graphics processing unit), and typically include chips and circuit elements (e.g., resistors, capacitors, inductors, etc.). Currently, in order to reduce the volume of power modules, some power module designs embed the chip inside the substrate. However, the chip can often generate significant heat during operation, and embedding chips inside the substrate can prevent the heat generated by the chips from being effectively transferred to the exterior of the power module, and this may result in poor heat dissipation performance of the power module.

### BRIEF DESCRIPTION OF THE DRAWINGS

FIG. 1 is a diagram of a first example power module, in accordance with embodiments of the present invention.

FIG. 2 is a diagram of a second example power module, in accordance with embodiments of the present invention.

FIG. 3 is a diagram of a third example power module, in accordance with embodiments of the present invention.

FIG. 4 is a diagram of a fourth example power module, in accordance with embodiments of the present invention.

FIG. 5 is a diagram of a first example substrate, in accordance with embodiments of the present invention.

FIG. 6 is a diagram of a first example inductor structure, in accordance with embodiments of the present invention.

FIG. 7 is a diagram of a second example inductor structure, in accordance with embodiments of the present invention.

FIG. 8 is a diagram of a third example inductor structure, in accordance with embodiments of the present invention.

FIG. 9 is a schematic diagram of a first example thermal conductive structure, in accordance with embodiments of the present invention.

FIG. 10 is a diagram of a second example thermal conductive structure, in accordance with embodiments of the present invention.

FIG. 11 is a diagram of an example power module reusing a winding as the thermal conductive structure, in accordance with embodiments of the present invention.

FIG. 12 is a diagram of an example winding reused as the thermal conductive structure, in accordance with embodiments of the present invention.

FIG. 13 is a diagram of an example magnetic core where a winding is reused as the thermal conductive structure, in accordance with embodiments of the present invention.

FIG. 14 is a diagram of a second example substrate, in accordance with embodiments of the present invention.

### DETAILED DESCRIPTION

Reference may now be made in detail to particular embodiments of the invention, examples of which are illustrated in the accompanying drawings. While the invention may be described in conjunction with the preferred embodiments, it may be understood that they are not intended to limit the invention to these embodiments. On the contrary, the invention is intended to cover alternatives, modifications and equivalents that may be included within the spirit and scope of the invention as defined by the appended claims. Furthermore, in the following detailed description of the present invention, numerous specific details are set forth in order to provide a thorough understanding of the present invention. However, it may be readily apparent to one skilled in the art that the present invention may be practiced without these specific details. In other instances, well-known methods, procedures, processes, components, structures, and circuits have not been described in detail so as not to unnecessarily obscure aspects of the present invention.

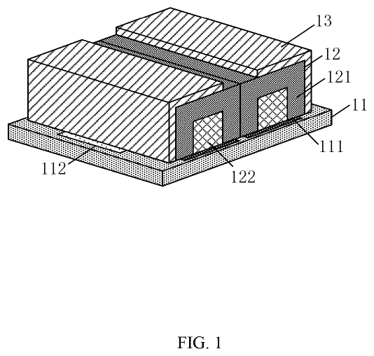

Referring now to FIG. 1, shown is a schematic diagram of a first example power module, in accordance with embodiments of the present invention. In this particular example, the power module can include substrate 11, at least one inductor structure 12, and thermal conductive structure 13. Substrate 11 may provide physical support for the power module, and achieve electrical connection between the power module and other components on a circuit board. The interior of substrate 11 can include at least one bare die, and the top surface of substrate 11 may be provided with first pad 111. For example, the bare die included in substrate 11 may be a control chip of the power module, or other related chips required to implement the function of the power module.

In one embodiment, inductor structure 12 can be disposed on the top surface of substrate 11 and may be connected to the bare die inside substrate 11 via first pad 111. For example, inductor structure 12 may include magnetic core 121 and winding 122, and the main body of winding 122 may be encapsulated inside magnetic core 121. The input and output ends of winding 122 may be exposed from two opposite side surfaces and/or the bottom surface of magnetic core 121 (e.g., the input and output ends of winding 122 may be led out from any surface of magnetic core 121) and can connect to corresponding first pad 111 provided on the top surface of substrate 11, in order to establish an electrical connection between inductor structure 12 and the bare die.

Thermal conductive structure 13 may be an independent structure. In one embodiment, thermal conductive structure 13 may at least semi-surround the outer surface of magnetic core 121. For example, thermal conductive structure 13 can semi-surround the top surface, side surfaces, and bottom surface of magnetic core 121. Further, thermal conductive structure 13 may include a first portion formed between the top surface of substrate 11 and the bottom surface of magnetic core 121, a second portion extending from the bottom surface of magnetic core 121 to the top surface of magnetic core 121, and a third portion formed on the top surface of magnetic core 121. For example, the third portion may completely cover the top surface of magnetic core 121, or partially cover the top surface of magnetic core 121, and the first, second, and third portions can connect together.

In one embodiment, during actual operation, heat generated by the bare die can be transferred to the exterior of the power module via the first, second, and third portions of thermal conductive structure 13. Thus, by forming and utilizing thermal conductive structure 13 as a heat conduction path for the bare die, particular embodiments can improve the heat dissipation performance of the power module when the chip is embedded inside the substrate. For example, the power module shown in FIG. 1 can include two inductor structures 12, but any suitable number of inductor structures included in the power module can be supported in certain embodiments. For example, two inductor structures 12 in the power module shown in FIG. 1 are closely attached to each other, but in other arrangements in particular embodiments, a certain gap may be left between multiple inductor structures. Further, when a gap is left between multiple inductor structures, in order to enhance the heat conduction effect achievable by the thermal conductive structure, the second portion of the thermal conductive structure may be formed within the gap between the inductor structures.

In addition to first pad 111, the top surface of substrate 11 may also be provided with second pad 112. Second pad 112 may be a ground pad, a floating pad, or a pad for connecting to an output pin of the power module, which may be connected to the bare die. In order to achieve a better heat conduction effect, the first portion of thermal conductive structure 13 may also be connected to the corresponding second pad 112. By connecting the first portion of thermal conductive structure 13 to second pad 112 used as the ground pad, this particular example can improve the anti-electromagnetic interference capability of the power module.

In particular embodiments, thermal conductive structure 13 may be made of a material with good thermal conductivity. In another example, thermal conductive structure 13 may be formed by deposition using one or more semiconductor processes, or may be assembled as a separate structure with other components. For example, to improve the heat conduction effect achievable by thermal conductive structure 13, particular embodiments may minimize the spatial distance between thermal conductive structure 13 and the bare die inside substrate 11. In order to achieve the above effect, particular embodiments may adjust the formation position of the first portion when forming thermal conductive structure 13, and can adjust the embedding position of the bare die when embedding the bare die inside substrate 11, such that in the subsequent power module, the first portion of thermal conductive structure 13 can be at least partially located above the bare die.

In order to further improve the heat conduction effect achievable by thermal conductive structure 13, the backside of the bare die in this example may be exposed from the top surface of substrate 11. Also, a thermal adhesive or form a thermal layer on the backside of the bare die can be applied, such that the backside of the bare die located inside substrate 11 can be connected to the first portion of thermal conductive structure 13 via the thermal adhesive or the thermal layer. In another example, in order to reduce the volume of the formed power module, when the backside of the bare die is connected to the first portion of thermal conductive structure 13 via the thermal layer, the bottom surface of the thermal layer may contact the backside of the bare die, and the top surface of the thermal layer may be flush with the top surface of the substrate. For example, the thermal layer may be made of a material with good thermal conductivity.

When the backside of the bare die cannot be exposed from the top surface of substrate 11, in order to improve the heat conduction effect achievable by thermal conductive structure 13, when embedding the bare die inside substrate 11, this particular example may also adjust the embedding depth of the bare die such that the thickness of the substrate material between the backside of the bare die and the top surface of substrate 11 is, e.g., less than or equal to 200 micrometers. In order to further help dissipate heat from the bare die, the third portion of thermal conductive structure 13 may be connected to a radiator provided externally. In another example, the third portion of thermal conductive structure 13 may be connected to the heat sink via a thermal adhesive. For example, when the power module includes a plurality of inductor structures, the third portions of the thermal conductive structure formed on the top surfaces of the respective magnetic cores may be connected together.

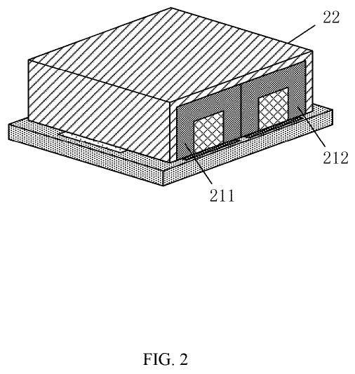

Referring now to FIG. 2, shown is a diagram of a second example power module, in accordance with embodiments of the present invention. In this particular example, the third portions of thermal conductive structure 22 formed on the top surfaces of magnetic cores 211 and 212 can connect together. For example, the power module in FIG. 2 may have the same structure as the power module in FIG. 1 except for the third portion of the thermal conductive structure. In one embodiment, for the power modules shown in FIGS. 1 and 2, the thickness and specific shape of the first, second, and third portions of the thermal conductive structure can be set according to the particular application.

Since the third portion of the thermal conductive structure can connect to a heat dissipation structure, in order to increase the connection area between them and enhance the heat dissipation effect, the coverage area of the third portion of the thermal conductive structure on the top surface of the magnetic core can be set as large as possible. For example, the coverage area of the third portion of the thermal conductive structure on the magnetic core may be larger than that of the first and second portions. Further, since the winding is exposed from the bottom surface of the magnetic core to connect to the pads, in order to avoid affecting the connection between the winding and the pads, the first portion of the thermal conductive structure may only cover the part of the bottom surface of the magnetic core where the winding is not exposed. For example, the coverage area of the first portion of the thermal conductive structure on the magnetic core may be smaller than that of the second and third portions.

In one example, the shape of the magnetic core of the inductor structure shown in FIG. 1 can be a rectangular cuboid, but in other examples, the shape of the magnetic core of the inductor structure may also be other shapes or irregular shapes. In order to prevent the shape of the magnetic core from affecting the specifications and shape of the power module, the thermal conductive structure can also ensure that the various surfaces of the power module are flush.

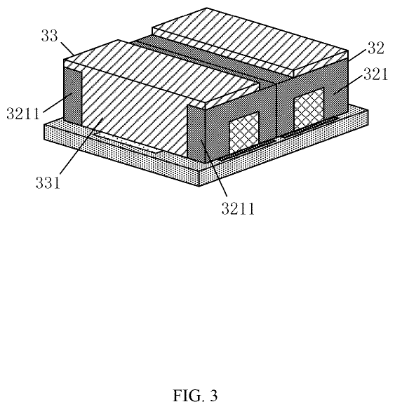

Referring now to FIG. 3, shown is a diagram of a third example power module, in accordance with embodiments of the present invention. In this particular example, magnetic core 311 of inductor structure 32 in FIG. 3 may include second protruding portion 3211 on its side surface. In one embodiment, the side surface of second portion 331 of thermal conductive structure 33 can be flush with the side surface of the second protruding portion, thereby ensuring that the side surface of the power module is flush.

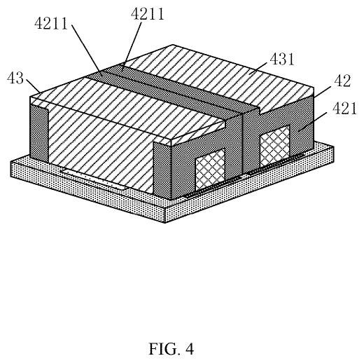

Referring now to FIG. 4, shown is a diagram of a fourth example power module, in accordance with embodiments of the present invention. In this particular example, magnetic core 421 of inductor structure 42 in FIG. 4 may include third protruding portion 4211 on its top. In one embodiment, the top of third portion 431 of thermal conductive structure 43 can be flush with the top of third protruding portion 4211, thereby ensuring that the top of the power module is flush. For example, the bottom surface of the magnetic core of the inductor structure can also have a corresponding first protruding portion. In this case, the bottom surface of the first portion of the thermal conductive structure can also be flush with the bottom surface of the first protruding portion.

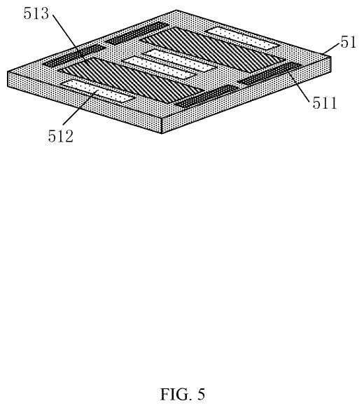

Referring now to FIG. 5, shown is diagram of a first example substrate, in accordance with embodiments of the present invention. For example, the substrate in FIG. 5 may be the substrate of the power module in FIG. 4. In this particular example, at least one bare die is embedded inside substrate 51. The top surface of substrate 51 can be provided with first pad 511 and second pad 512. First pad 511 may achieve electrical connection between the bare die inside substrate 51 and the inductor structure. Second pad 512 may be a ground pad, a floating pad, or a pad for connecting to an output pin of the power module, and can connect to the bare die inside substrate 51.

For example, the number of first pad 511 can be determined according to the number of inductor structures in the power module. The arrangement position of first pad 511 can be determined according to the exposed positions of the input and output terminals of the inductor structure. The number of second pad(s) 512 can be determined according to the number of bare dies inside substrate 51 and the particular needs of each bare die. The arrangement position of second pad 512 can match the formation position of the first portion of the thermal conductive structure, in order to ensure that second pad 512 can connect to the first portion of the thermal conductive structure.

In one embodiment, in order to improve the heat conduction effect achievable by the thermal conductive structure, the top surface of substrate 51 may expose the backside of the bare die. Further, a recess for exposing the backside of the bare die may be formed, and the recess may be filled with a thermal layer 513. In order to reduce the volume of the formed power module, the bottom surface of thermal layer 513 may contact the backside of the bare die, and the top surface of thermal layer 513 may be flush with the top surface of substrate 51.

For example, in addition to the bare die, circuit elements (e.g., resistors, capacitors, etc.) may also be embedded inside substrate 51. In order to achieve electrical connection between the power module and other components on the circuit board, and between the inductor structure and the bare die and circuit elements inside substrate 51, corresponding conductive paths and conductive vias may be embedded inside substrate 51. Further, pads 511 and 512 can establish electrical connection with the bare die through the conductive paths and the conductive vias.

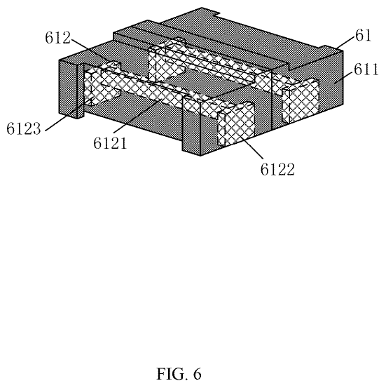

Referring now to FIG. 6, shown is a diagram of a first example inductor structure, in accordance with embodiments of the present invention. For example, the inductor structure in FIG. 6 may be the inductor structure of the power module in FIG. 4 (e.g., the power module in FIG. 4 can include two inductor structures closely attached to each other). To show the structural relationship between the magnetic core and the winding, perspective processing can be performed on the inductor structure. In this particular example, the inductor structure 61 may include magnetic core 611 and winding 612. Further, main body 6121 of winding 612 may be encapsulated inside magnetic core 611. Input end 6122 and output end 6123 of winding 612 may be exposed from two opposite side surfaces and the bottom surface of magnetic core 611, respectively. For example, the exposed input end 6122 and output end 6123 can connect to the corresponding first pads provided on the top surface of the substrate, thereby establishing an electrical connection between the inductor structure and the bare die.

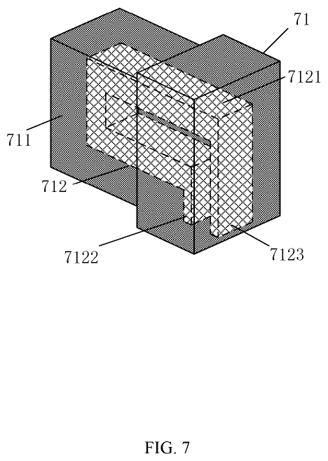

Referring now to FIG. 7, shown is a diagram of a second example inductor structure, in accordance with embodiments of the present invention. FIG. 7 shows one inductor structure. In this particular example, the magnetic core 711 of inductor structure 71 may be a rectangular cuboid having protruding portions on its bottom surface, top surface, and side surfaces, respectively. Alternatively, magnetic core 711 of inductor structure 71 can also be seen as two connected rectangular cuboids. Further, main body 7121 of winding 712 of inductor structure 71 can include two parallel parts and is also encapsulated inside magnetic core 711. However, input end 7122 and output end 7123 of winding 712 may be exposed from the same protruding portion on the bottom surface of the magnetic core 711. For example, in order to adapt to inductor structure 71, the arrangement positions of the first and second pads on the top surface of the substrate and the shape of the thermal conductive structure can be adjusted according to particular needs.

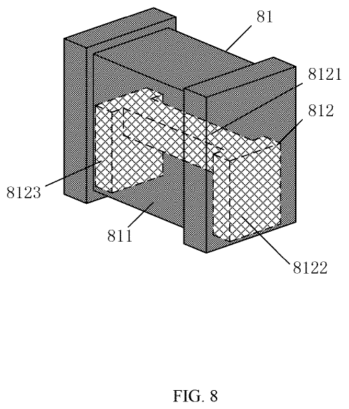

Referring now to FIG. 8, shown is a diagram of a third example inductor structure, in accordance with embodiments of the present invention. This particular example shows one inductor structure, and as compared to the inductor structures in FIGS. 6 and 7, magnetic core 811 of inductor structure 81 may be a rectangular cuboid having multiple protruding portions on its bottom, top, and side surfaces, respectively. Alternatively, magnetic core 811 of inductor structure 81 can also be seen as three connected rectangular cuboids. Further, main body 8121 of winding 812 may also be encapsulated inside magnetic core 811. However, input end 8122 and output end 8123 of winding 812 may be exposed from two different protruding portions on the bottom surface of magnetic core 811, respectively. For example, in order to adapt to inductor structure 81, the arrangement positions of the first and second pads on the top surface of the substrate and the shape of the thermal conductive structure can be adjusted according to particular needs.

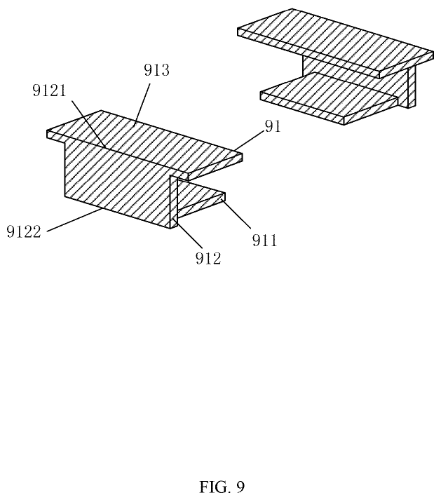

Referring now to FIG. 9, shown is a diagram of a first example thermal conductive structure, in accordance with embodiments of the present invention. For example, the thermal conductive structure here may be the thermal conductive structure of the power module in FIG. 4. The thermal conductive structure on the left side of FIG. 9 and the one on the right side may be identical (e.g., the two thermal conductive structures can be respectively installed on the two inductor structures in FIG. 6). The following description will use one of them for explanation.

In this particular example, the thermal conductive structure may include first portion 911, second portion 912, and third portion 913 connected together. First portion 911 may be formed between the top surface of the substrate and the bottom surface of the magnetic core of the inductor structure. For example, when the backside of the bare die is exposed from the top surface of the substrate, first portion 911 can connect to the bare die inside the substrate via a thermal adhesive or a thermal layer. For example, when the bottom surface of the magnetic core of the inductor structure has a first protruding portion, the bottom surface of first portion 911 may be flush with the bottom surface of the first protruding portion.

Second portion 912 may be formed on two opposite side surfaces of the magnetic core of the inductor structure. Further, each second portion 912 may have first end 9121 and second end 9122 located opposite to each other. By way of first end 9121, the second portion can connect to third portion 913. By way of second end 9122, the second portion may be connected to first portion 911. For example, when the side surface of the magnetic core of the inductor structure has a second protruding portion, the side surface of second portion 912 may be flush with the side surface of the second protruding portion. Third portion 913 can be formed on the top surface of the magnetic core of the inductor structure. For example, when the top surface of the magnetic core of the inductor structure has a third protruding portion, the top surface of third portion 913 may be flush with the top surface of the third protruding portion. In one example, third portion 913 can connect to a radiator. The third portions of the two thermal conductive structures in this particular example are two separate parts, but in other examples, the third portions of the two thermal conductive structures may be an integral whole (e.g., as shown by the thermal conductive structure 22 in FIG. 2).

For example, the thermal conductive structure in FIG. 9 may only cover one side surface of the inductor structure, the first and third portions are arranged perpendicular to the second portion, and can be seen as a “□”-shaped structure. In other embodiments, the second portion of the thermal conductive structure may respectively cover two opposite side surfaces of the inductor structure. In this case, the thermal conductive structure can be seen as two symmetrical “□”-shaped structures spliced together.

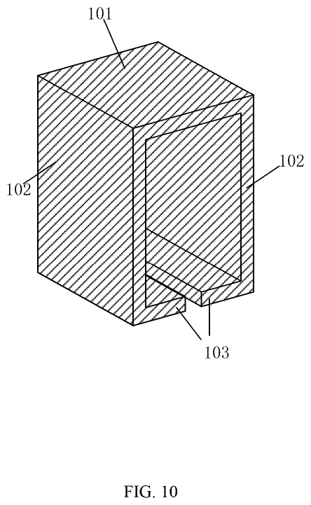

Referring now to FIG. 10, shown is a diagram of a second example thermal conductive structure, in accordance with embodiments of the present invention. For example, the thermal conductive structure in FIG. 10 may be applicable to the inductor structure in FIG. 7 or 8. In this particular example, the thermal conductive structure may include first portion 103, second portion 102, and third portion 101 connected together. First portion 103 may be formed between the top surface of the substrate and the bottom surface of the magnetic core of the inductor structure. Second portion 102 may be formed on two opposite side surfaces of the magnetic core of the inductor structure. Third portion 101 may be formed on the top surface of the magnetic core of the inductor structure.

The first and third portions can be arranged perpendicular to the second portion, and first portion 103, second portion 102, and third portions 101 of the thermal conductive structures can be seen as a “□”-shaped structure. In this case, the thermal conductive structure can be seen as two symmetrical “□”-shaped structures spliced together. For example, FIG. 10 may show the case where the third portions of the thermal conductive structure are spliced together, but in particular applications, the first portions of the thermal conductive structure may also be spliced together. In addition to being configured as an independent structure, the thermal conductive structure may also at least partially reuse a portion of the inductor structure. Here, this example may reuse the winding in the inductor structure as the thermal conductive structure.

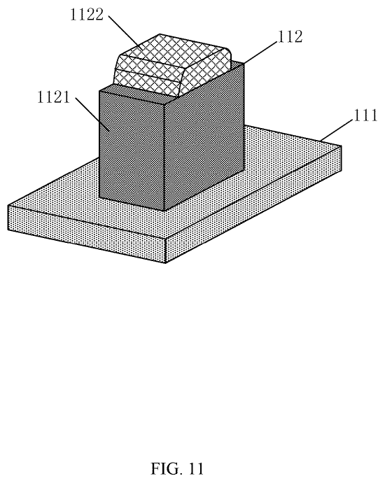

Referring now to FIG. 11, shown is a diagram of an example power module reusing a winding as the thermal conductive structure, in accordance with embodiments of the present invention. In this particular example, power module can include substrate 111 and inductor structure 112. Inductor structure 112 can be disposed on the top surface of substrate 111. The inductor structure 112 can include magnetic core 1121 and winding 1122. Further, winding 1122 is reused as the thermal conductive structure. Winding 1122 may extend from the bottom surface of magnetic core 1121 to the top surface of magnetic core 1121, and can be exposed from both the bottom surface and the top surface of magnetic core 1121.

For example, the portion of winding 1122 exposed at the bottom surface of magnetic core 1121 may serve as the first portion of the thermal conductive structure, the portion of winding 1122 located inside magnetic core 1121 serves as the second portion of the thermal conductive structure, and the portion of winding 1122 covering the top surface of magnetic core 1121 may serve as the third portion of the thermal conductive structure. Correspondingly, substrate 111 may also have at least one bare die embedded inside, and its top surface may be provided with first pads. The first portion of winding 1122 can connect to the bare die via the first pads. In this case, the backside of the bare die cannot be exposed from the top surface of the substrate, but in order to improve the heat conduction effect achievable by the thermal conductive structure, the thickness of the substrate material between the backside of the bare die and the top surface of substrate 111 may be set to be e.g., not greater than 100 micrometers.

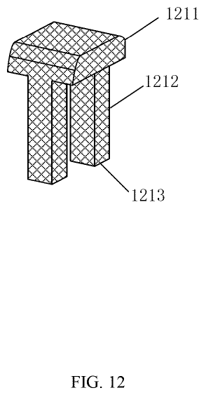

Referring now to FIG. 12, shown is a diagram of an example winding reused as the thermal conductive structure, in accordance with embodiments of the present invention. In this particular example, the winding may include first portion 1213, second portion 1212, and third portion 1211 connected together. First portion 1213 may be formed between the top surface of the substrate and the bottom surface of the magnetic core of the inductor structure. As compared to the thermal conductive structure as an independent structure in the above examples, in performing the function of the winding itself, the first portion 1213 can contact the first pad provided on the substrate, in order to establish an electrical connection between the inductor structure and the bare die. Further, second portion 1212 can be located inside the magnetic core, e.g., formed on the inner side surface of the magnetic core. Second portion 1212 can connect first portion 1213 and third portion 1211. For example, third portion 1211 can be formed on the top surface of the magnetic core, and can connect to a radiator.

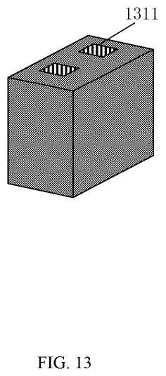

Referring now to FIG. 13, shown is a diagram of an example magnetic core where a winding is reused as the thermal conductive structure, in accordance with embodiments of the present invention. In this particular example, the magnetic core may have through hole 1311, which can accommodate the second portion of the winding. In this example, the shape of the magnetic core can be a rectangular cuboid, but in other examples, the magnetic core may adopt other shapes.

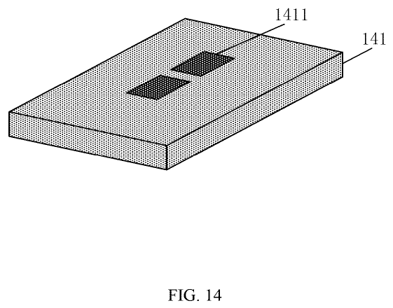

Referring now to FIG. 14, shown is a diagram of a second example substrate, in accordance with embodiments of the present invention. In this particular example, substrate 141 may have a structure similar to substrate 51 in FIG. 5, but here the top surface of substrate 141 may be only provided with first pad 1411. The inductor structure can be disposed above first pad 1411 and contact the first portion of the winding of the inductor structure, in order to establish an electrical connection between the inductor structure and the bare die.

The power module in particular embodiments can include a substrate, at least one inductor structure, and a thermal conductive structure. The interior of the substrate can include at least one bare die, and its top surface may be provided with a first pad. The inductor structure can be disposed on the top surface of the substrate and can connect to the bare die via the first pad. The inductor structure can include a magnetic core. The thermal conductive structure can at least partially reuse a portion of the inductor structure, or may be an independent structure. The thermal conductive structure can include a first portion formed between the top surface of the substrate and a bottom surface of the magnetic core, a second portion extending from the bottom surface of the magnetic core to a top surface of the magnetic core, and a third portion formed on the top surface of the magnetic core. The first, second, and third portions can connect together. Thus, by forming and utilizing the thermal conductive structure as a heat conduction path for the bare die, particular embodiments can improve the heat dissipation performance of the power module when the chip is embedded inside the substrate.

In particular embodiments, the switches can adopt various existing types of electrically controllable switches, such as any suitable type of transistor (e.g., metal oxide semiconductor field effect transistor [MOSFET], bipolar junction transistor [BJT], insulated gate bipolar transistor [IGBT], etc.).

The embodiments were chosen and described in order to best explain the principles of the invention and its practical applications, to thereby enable others skilled in the art to best utilize the invention and various embodiments with modifications as are suited to particular use(s) contemplated. It is intended that the scope of the invention be defined by the claims appended hereto and their equivalents.

What is claimed is:

1. A power module, comprising:
a) a substrate, comprising an interior having at least one bare die, and a top surface having a first pad;
b) at least one inductor structure disposed on the top surface of the substrate, being configured to electrically connected to the bare die via the first pad, and having a magnetic core; and
c) a thermal conductive structure, comprising a first portion formed between the top surface of the substrate and a bottom surface of the magnetic core, a second portion extending from the bottom surface of the magnetic core to a top surface of the magnetic core, and a third portion formed on the top surface of the magnetic core, wherein the first portion, the second portion, and the third portion are connected together.

2. The power module of claim 1, wherein the third portion of the thermal conductive structure is configured to be thermally connected to a radiator.

3. The power module of claim 1, wherein at least part of the first portion of the thermal conductive structure is located above the bare die.

4. The power module of claim 3, wherein a backside of the bare die is exposed by the top surface of the substrate, and the backside of the bare die is connected to the first portion of the thermal conductive structure via a thermal layer.

5. The power module of claim 4, wherein the backside of the bare die is thermally connected to the first portion of the thermal conductive structure via the thermal layer, a bottom surface of the thermal layer contacts the backside of the bare die, and a top surface of the thermal layer is substantially flush with the top surface of the substrate.

6. The power module of claim 3, wherein a thickness of substrate material between a backside of the bare die and the top surface of the substrate is not greater than 200 micrometers.

7. The power module of claim 1, wherein the thermal conductive structure is an independent structure comprising a winding at least partially encapsulated by the magnetic core, and wherein the thermal conductive structure at least semi-surrounds an outer surface of the magnetic core.

8. The power module of claim 7, wherein the top surface of the substrate is further provided with a second pad, and the first portion of the thermal conductive structure is connected to the second pad.

9. The power module of claim 8, wherein the second pad is configured as one of: a ground pad, a floating pad, and a pad for connecting to an output pin of the power module.

10. The power module of claim 7, wherein at least one of:
a) the bottom surface of the magnetic core has a first protruding portion, and a bottom surface of the first portion of the thermal conductive structure is substantially flush with a bottom surface of the first protruding portion;
b) a side surface of the magnetic core has a second protruding portion, and a side surface of the second portion of the thermal conductive structure is substantially flush with a side surface of the second protruding portion; and
c) the top surface of the magnetic core has a third protruding portion, and a top surface of the third portion of the thermal conductive structure is substantially flush with a top surface of the third protruding portion.

11. The power module of claim 7, wherein:
a) the second portion of the thermal conductive structure covers at least one side surface of the magnetic core; and
b) the second portion covering each side surface of the magnetic core comprises a first end and a second end located opposite to each other, the second portion covering each side surface is connected to the third portion via the first end, and to the first portion via the second end.

12. The power module of claim 11, wherein the second portion of the thermal conductive structure covers two opposite side surfaces of the magnetic core, and the first portion and the third portion are arranged perpendicular to the second portion.

13. The power module of claim 11, wherein the third portion of each of the thermal conductive structures comprises a single unit or two separate parts.

14. The power module of claim 11, wherein the second portion of the thermal conductive structure covers one side surface of the magnetic core, and the first portion and the third portion are arranged perpendicular to the second portion.

15. The power module of claim 1, wherein the power module comprises a plurality of inductor structures, and the third portions of the thermal conductive structure covering the top surface of the magnetic core of each of the inductor structures are connected to each other.

16. The power module of claim 1, wherein:
a) the thermal conductive structure at least partially reuses a portion of the inductor structure;
b) the inductor structure further comprises a winding, the winding extends from the bottom surface of the magnetic core to the top surface of the magnetic core and is exposed from both the bottom surface and the top surface of the magnetic core;
c) a portion of the winding exposed at the bottom surface of the magnetic core serves as the first portion of the thermal conductive structure;
d) a portion of the winding located inside the magnetic core serves as the second portion of the thermal conductive structure; and
e) a portion of the winding covering the top surface of the magnetic core serves as the third portion of the thermal conductive structure.

17. The power module of claim 16, wherein the first pad is electrically connected to the first portion of the thermal conductive structure.

18. The power module of claim 16, wherein a thickness of substrate material between a backside of the bare die and the top surface of the substrate is not greater than 100 micrometers.

19. The power module of claim 1, wherein the thermal conductive structure at least partially reuses a portion of the inductor structure or is an independent structure.

20. The power module of claim 1, wherein a backside of the bare die is exposed by the top surface of the substrate, and the backside of the bare die is connected to the first portion of the thermal conductive structure via a thermal interface material.
